(19) United States
(12) Patent Application Publication
(10) Pub. No.: US 2007/0146995 A1
(43) Pub. Date: Jun. 28, 2007

(54) HEAT DISSIPATION DEVICE

(76) Inventors: Liang-Hui Zhao, Shenzhen (CN); Yi-Qiang Wu, Shenzhen (CN); Chun-Chi Chen, Shenzhen (CN)

Correspondence Address: NORTH AMERICA INTELLECTUAL PROPERTY CORPORATION, P.O. BOX 506, MERRIFIELD, VA, 22116, US

(21) Appl. No.: 11/306,415

(22) Filed: Dec. 27, 2005

(51) Int. Cl. H05K 7/20

(52) U.S. Cl. 361/697

(57) ABSTRACT

A heat dissipation device includes a heat spreader (100) for contacting a heat-generating component, a heat sink (200) mounted on the heat spreader, a fan (300) mounted on the heat sink, a heat-dissipating component (400), and a heat pipe (500) thermally connecting the heat spreader, the heat sink and the heat-dissipating component together. The heat sink comprises a core (210) having an axis substantially perpendicular to the heat spreader, and a plurality of fins (220) outwardly and radially extending from the core.

### FIELD OF THE INVENTION

The present invention relates to a heat dissipation device, and more particularly to a heat dissipation device having heat pipes connecting multiple heat sinks together for achieving great heat dissipation efficiency.

### DESCRIPTION OF RELATED ART

As computer technology continues to advance, electronic components such as central processing units (CPUs) of computers are made to provide faster operational speeds and greater functional capabilities. When a CPU operates at a high speed in a computer enclosure, its temperature usually increases greatly. It is desirable to dissipate the generated heat of the CPU quickly.

Conventionally, a heat dissipation device is used to dissipate heat generated by the CPU. A conventional heat dissipation device comprises a heat sink and a fan disposed on the heat sink. The heat sink comprises a base and a plurality of fins set up straightly on the base. The fan comprises a hub and a plurality of blades extending radially from the hub. The fan produces an airflow blown downwardly to the heat sink. However, when the airflow blows to the base, the airflow will rebound from the base, which adversely affects the dissipation of the heat from the fins. Furthermore, a portion of the heat sink, especially the portion of the heat sink under the hub of the fan, is not subject to the airflow. Therefore, the heat of this portion of the heat sink is not dissipated efficiently. Accordingly, the conventional heat dissipation device can not dissipate heat quickly and the heat dissipation efficiency of the conventional heat dissipation device is low.

What is needed, therefore, is a heat dissipation device with a great heat dissipation efficiency.

### SUMMARY OF INVENTION

A heat dissipation device in accordance with a preferred embodiment of the present invention, comprises a heat spreader, a heat sink mounted on the heat spreader, a fan mounted on the heat sink, a heat-dissipating component, and a heat pipe thermally connecting the heat spreader, the heat sink and the heat-dissipating component together. The heat spreader is for contacting with a heat-generating electronic component in an electronic system. The fan generates an airflow blown downwardly to the heat sink. The heat sink comprises a core having an axis substantially perpendicular to the heat spreader, and a plurality of fins outwardly and radially extending from the core. The heat dissipation device further comprises a second fan mounted on the heat-dissipating component for generating an airflow through the heat-dissipating component to an outside of the electronic system.

Other advantages and novel features will become more apparent from the following detailed description of preferred embodiments when taken in conjunction with the accompanying drawings, in which:

### BRIEF DESCRIPTION OF DRAWINGS

FIG. 1 is an assembled view of a heat dissipation device in accordance with a preferred embodiment of the present invention;

FIG. 2 is a partially exploded view of the heat dissipation device of FIG. 1;

FIG. 3 is a bottom view of a heat sink of the heat dissipation device of FIG. 1;

FIG. 4 is an assembled view of the heat dissipation device with a second fan mounted thereon; and

FIG. 5 is a partially exploded view of the heat dissipation device of FIG. 4.

### DETAILED DESCRIPTION

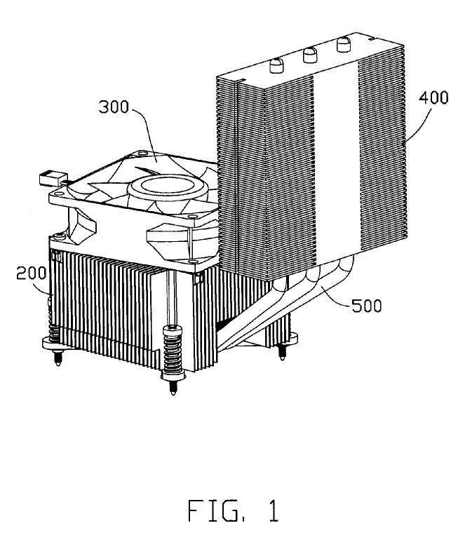

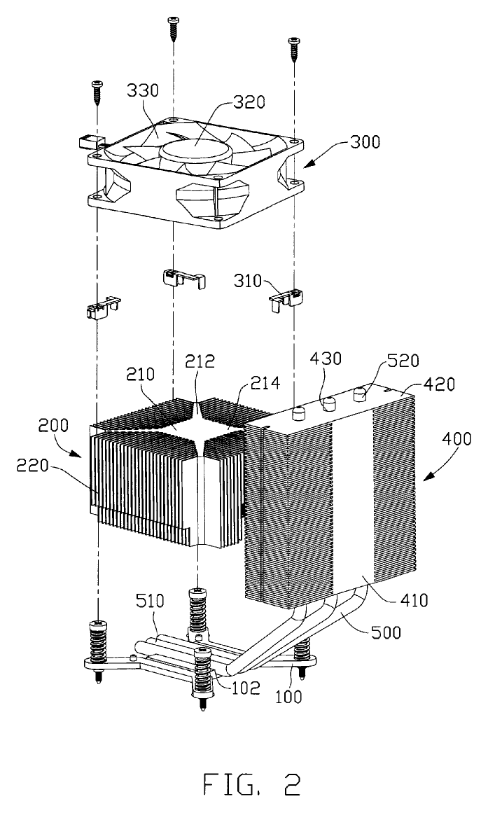

Referring to FIGS. 1-2, a heat dissipation device in accordance with a preferred embodiment of the invention comprises a heat spreader 100, a heat sink 200 mounted on the heat spreader 100, a fan 300 mounted on the heat sink 200 through fan holders 310, a heat-dissipating component 400 located at a lateral side of the heat sink 200 and a heat conductive member such as three heat pipes 500 thermally connecting the heat spreader 100, the heat sink 200 and the heat-dissipating component 400 together. The fan 300 comprises a hub 320 and a plurality of blades 330 extending radially from the hub 320.

The heat spreader 100 is for contacting an electronic component such as a CPU (not shown) received in an electronic system such as a computer. The heat spreader 100 is made of heat conductive material such as copper, aluminum, and has three parallel first grooves 102 defined therein. Preferably, the heat spreader 100 is made of copper, which has a better heat conductivity than aluminum.

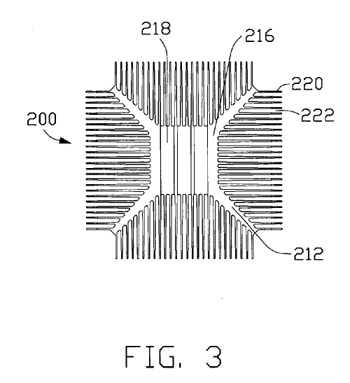

Referring also to FIG. 3, the heat sink 200 is an aluminum extrusion type heat sink. The heat sink 200 comprises a rectangular solid core 210 with four legs 212 extending outwardly and radially from four corners of the core 210, respectively, and a plurality of fins 220 projecting outwardly and radially from an outer periphery of the core 210. The core 210 is located under the hub 320 of the fan 300 and has an axis substantially perpendicular to the heat spreader 100. The core 210 comprises an upper surface 214 adjacent to the fan 300, and a bottom portion 216 facing to the heat spreader 100. The size of the core 210 is not smaller than that of the heat spreader 100. Three second grooves 218 are defined in the bottom portion 216 of the core 210. The first and second grooves 102, 218 together form three passages to receive evaporators 510 of the heat pipes 500. A plurality of channels 222 is defined between adjacent fins 220 and extends from upper surface 214 to the bottom portion 216 of the core 210. An airflow generated by the fan 300 flows downwardly along the channels 222 to exchange heat with the heat sink 200 and finally cools down the CPU and other electronic components surrounding the CPU.

The heat-dissipating component 400 comprises a prism-shaped block 410 having an axis parallel to the axis of the core 210, and a plurality of heat-dissipating fins 420 extending from two opposite sides of the block 410 and parallel to the heat spreader 100. Three parallel holes 430 are defined through the heat-dissipating component 400 to receive condensers 520 of the heat pipes 500. One of the holes 430 extends through the block 410, and the other two of the holes 430 extend perpendicularly through the heat-dissipating fins 420, respectively. The heat-dissipating component 400 can be manufactured by aluminum extrusion or other methods such as by soldering the fins 420 to the block 410.

The evaporators 510 of the heat pipes 500 are horizontally received in the passages defined by the first and second grooves 102, 218. The condensers 520 of the heat pipes 500 are vertically received in the holes 430. The heat pipes 500 further have slanted adiabatic sections (not labeled) interconnecting the evaporators 510 and the condensers 520.

In operation of the heat dissipation device of the preferred embodiment of the invention, the fan 300 blows airflow downwardly along the channels 222 defined between the fins 220 of the heat sink 200, and part of heat originated from the CPU is dissipated to ambient air by the airflow directly. Other part of the heat originated from the CPU is absorbed by the heat spreader 100. A part of the heat absorbed by the heat spreader 100 is directly transferred to the core 210 and then to the fins 220 to be dissipated. The other part of the heat absorbed by the heat spreader 100 is transferred to the evaporators 510 of the heat pipes 500, and then is quickly transferred to the heat-dissipating component 400 through condensers 520 of the heat pips 500.

As the size of the heat spreader 100 is not bigger than that of the core 210, airflow produced by the fan 300 will not rebound from the heat spreader 100. As we known, since a portion of the heat sink 200 under the hub 320 of the fan 300, can not be blown by the airflow produced by the fan 300, the core 210 wherein no air channel is formed is set up straightly on the heat spreader 100 and located under the hub 320 of fan 300. The core 210 absorbs the heat from the heat spreader 100 and then conducts the heat to the fins 220. This avails to efficiently use the portion of the heat sink 200 under the hub 320 of the fan 300 to dissipate the heat from the CPU.

The part of the heat of the CPU which is transferred to the heat-dissipating component 400 located at a lateral side of the heat sink 200 through the heat pipes 500 is cooled down by the heat-dissipating component 400. This avails to efficiently use space surrounding the heat sink 200 to dissipate the heat. Especially in a situation that the space occupied by the heat sink 200 is limited, the heat sink 200 can not be too high; the heat-dissipating component 400 can help the heat sink 200 to effectively dissipate the heat of the CPU.

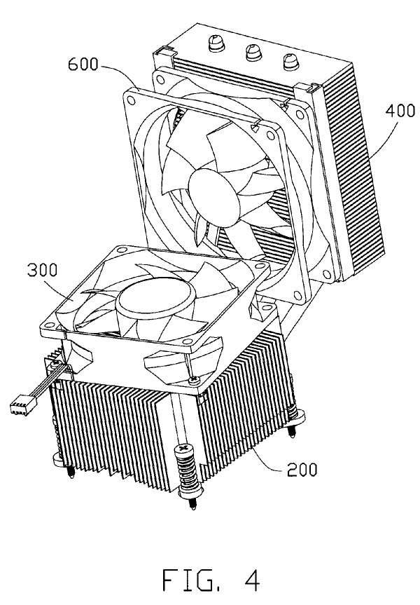

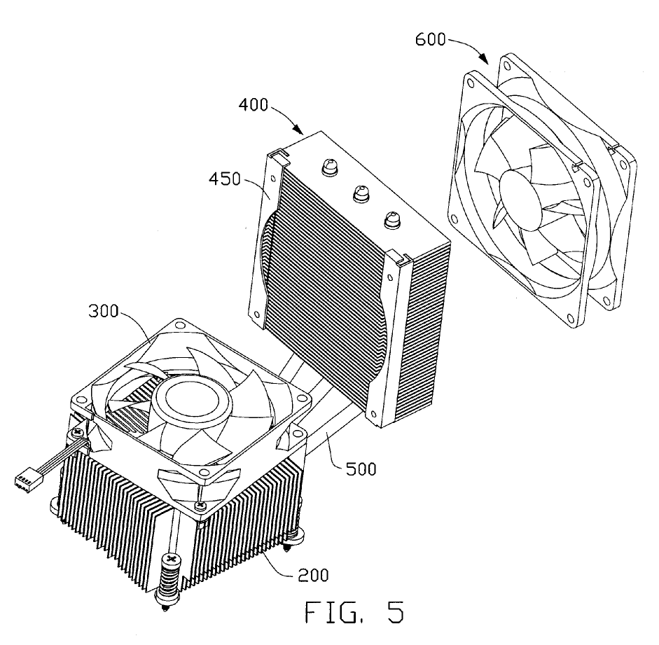

FIGS. 4-5, illustrate a second fan 60 mounted on the heat-dissipating component 400 through a pair of fan holders 450. A pair of slots (not labeled) is formed on two opposite sides of the heat-dissipating component 400. The fan holders 450 engage with the corresponding slots, and the second fan 600 is screwed on the fan holders 450. In use, the heat-dissipating component 400 is mounted adjacent to an opening defined in an enclosure of the computer. Therefore, the second fan 600 functions as a system fan for the computer. The second fan 600 generates an airflow which can draw heat in the computer to an ambient environment outside the computer enclosure. When the second fan 600 operates, the heat of the CPU transferred to the heat-dissipating component 400 is taken away to the ambient environment by the airflow of the second fan 600. The second fan 600 and the fan 300 are oriented perpendicular to each other.

In the preferred embodiment, the connections between the heat spreader 100, the heat sink 200 and the heat pipes 500, and between the heat pipes 500 and the heat-dissipating component 400 are achieved by soldering.

It is believed that the present embodiments and their advantages will be understood from the foregoing description, and it will be apparent that various changes may be made thereto without departing from the spirit and scope of the invention or sacrificing all of its material advantages, the examples hereinbefore described merely being preferred or exemplary embodiments of the invention.

1. A heat dissipation device comprising:
a heat spreader for contacting a heat-generating component;
a heat sink mounted on the heat spreader, the heat sink comprising a solid core having an axis perpendicular to the heat spreader, and a plurality of fins outwardly and radially extending from the core;
a fan mounted on the heat sink;
a heat-dissipating component; and
a heat pipe thermally connecting the heat spreader, the heat sink and the heat-dissipating component together.

2. The heat dissipation device as claimed in claim 1, wherein the heat-dissipating component comprises a block having an axis parallel to the axis of the core, and a plurality of heat-dissipating fins extending from the block and parallel to the heat spreader.

3. The heat dissipation device as claimed in claim 2, wherein a through hole is defined through the block for accommodating the heat pipe.

4. The heat dissipation device as claimed in claim 3, wherein the heat-dissipating fins are set up on opposite sides of the block.

5. The heat dissipation device as claimed in claim 4, further comprising another heat pipe thermally connecting the heat spreader, the heat sink and the heat-dissipating component together.

6. The heat dissipation device as claimed in claim 5, wherein another hole is defined through the heat-dissipating fins for accommodating the another heat pipe.

7. The heat dissipation device as claimed in claim 4, further comprising another fan mounted on the heat-dissipating component.

8. The heat dissipation device as claimed in claim 1, wherein the fan and the another fan are oriented perpendicular to each other.

9. The heat dissipation device as claimed in claim 8, wherein the heat-dissipating component is adapted to be mounted adjacent to an opening defined in an enclosure for enclosing the heat-generating component.

10. A heat dissipation device comprising:
a horizontal heat spreader for contacting a heat-generating component;
a first heat sink comprising a vertical core set up straightly on the heat spreader, and a plurality of fins extending outwardly from the core, the core having a heat conductivity no less than that of the fins;
a fan mounted on the first heat sink to blow air passing through the fins of the first heat sink;
a second heat sink comprising a block parallel to the core of the first heat sink, and a plurality of heat-dissipating fins mounted on the block; and
a heat pipe thermally connecting the heat spreader, the core of the first heat sink and the block of the second heat sink together.

11. The heat dissipation device as claimed in claim 10, wherein the block has a prism-shaped configuration.

12. The heat dissipation device as claimed in claim 11, wherein the heat-dissipating fins are mounted on two opposite sides of the block.

13. The heat dissipation device as claimed in claim 10, wherein the first and second heat sinks are aluminum extrusion type heat sinks.

14. A heat dissipation device comprising:
a first heat sink adapted for contacting with a heat-generating electronic component of an electronic system;
a second heat sink adapted for being mounted adjacent to an enclosure of the electronic system;
a fan positioned adjacent to the second heat sink and adapted for generating an airflow through the second heat sink and the enclosure; and
a heat pipe having an evaporator in thermal connection with the first heat sink and a condenser in thermal connection with the second heat sink;
wherein the first heat sink has a vertical core and a plurality of fins extending outwardly from and encircling the core.

15. The heat dissipation device of claim 14, further comprising an additional fan mounted on the first heat sink.

16. The heat dissipation device of claim 14, wherein the condenser is vertically oriented and the evaporator is horizontally oriented.

17. The heat dissipation device of claim 15, wherein the two fans are oriented substantially perpendicular to each other.

18. The heat dissipation device of claim 14, further comprising a heat spreader made of copper and attached to a bottom of the first heat sink adapted for contacting with the heat-generating electronic component, the evaporator being sandwiched between the first heat sink and the heat spreader.

19. The heat dissipation device of claim 16, wherein the heat pipe has a slanted adiabatic section interconnecting the condenser and the evaporator.

20. The heat dissipation device of claim 14, wherein the fins define a plurality of channels vertically extending through top and bottom of the first heat sink.
